(19) United States
(12) Patent Application Publication
(10) Pub. No.: US 2015/0171272 A1
(43) Pub. Date: Jun. 18, 2015

(54) SEMICONDUCTOR PLATE DEVICE

(71) Applicant: Zhijiong Luo, Hopewell Township, PA (US)

(72) Inventor: Zhijiong Luo, Hopewell Township, PA (US)

(21) Appl. No.: 14/567,720

(22) Filed: Dec. 11, 2014

Related U.S. Application Data
(60) Provisional application No. 61/915,482, filed on Dec. 12, 2013.

(51) Int. Cl. H01L 33/20; H01L 31/18; H01L 33/00; H01L 31/0352

(52) U.S. Cl. CPC H01L 33/20; H01L 31/035272; H01L 31/1876; H01L 33/005

(57) ABSTRACT

Technologies are generally described for providing solar device or LED device structures and methods for manufacturing the same, which may allow for making ultra-thin semiconductor plate devices with flexible contact arrangements at the meantime of maintaining or improving performance of solar devices, improving the utility of the semiconductor plate material, and increasing the fabrication through-put and yield of the solar and LED devices.

### CROSS REFERENCE TO RELATED APPLICATIONS

This application claims the benefit under 35 of U.S.C. §119(e) of U.S. Provisional Patent Application Ser. No. 61/915,482 filed on Dec. 12, 2013. The disclosure of the provisional patent application is hereby incorporated by reference in its entirety.

### FIELD OF THE DISCLOSURE

The present disclosure relates to the technical field of semiconductor devices, specifically, to solar devices and manufacturing of the devices. The present disclosure may also relate to light-emitting diode (LED) devices and manufacturing of the devices.

### BACKGROUND

Due to a growing concern of energy shortage and environmental challenges, solar energy has been regarded as a potential solution. At the heart of the photovoltaic industry are solar cells, which convert photon energy into electrical energy. With rapid technological advancements in the photovoltaic industry, solar cells have been widely used in various applications. Advances may be needed for further efficient usage of the solar cells. One solution may include the manufacturing of thin crystalline silicon based solar cells (i.e. less than 120 μm). Not only is it difficult to manufacture such thin devices, but it is also very difficult to maintain the efficiency of ultra-thin solar cells. Moreover, in solar structures, electrodes are built on surfaces of solar cells, which may block light and may degrade energy conversion efficiency of the solar cells. Furthermore, high efficiency solar cells typically involve expensive semiconductor film deposition. So, the high efficiency solar cells typically require high throughput process and technologies to reduce the cost of high efficiency solar cells; the same technique may be applied to LED manufacturing process. New device structures and methods for manufacturing the same may be needed to solve the aforementioned problems.

### SUMMARY

This summary is provided to introduce a selection of concepts in a simplified form that are further described below in the Detailed Description. This summary is not intended to identify mere features of the claimed subject matter, nor is it intended as an aid in determining the scope of the claimed subject matter.

Examples are directed to semiconductor devices, more specifically, the examples are directed to solar devices, and some examples may include LED devices.

Technologies are generally described for providing solar device or LED device structures and methods for manufacturing the same, which may allow for making ultra-thin semiconductor plate devices with flexible contact arrangements at the meantime of maintaining or improving performance of solar devices, improving the utility of the semiconductor plate material, and increasing the fabrication through-put and yield of the solar and LED devices.

The solar devices provided according to the present disclosure may be capable of effectively collecting photogenic charge carriers, which may improve electrical current density of solar cells and may improve conversion efficiency. The devices may also be bi-facial. The devices may absorb light or emit light from its surfaces.

Examples are directed to solar and LED devices. An example semiconductor device may include a semiconductor plate. The semiconductor plate may have a first main surface and a second main surface opposite to the first surface. The semiconductor plate may include at least one first-type doping region and at least one second-type doping region incorporated into the semiconductor plate on the first main surface and at least one other first-type doping region and at least one other second-type doping region incorporated into the semiconductor plate on the second main surface. The semiconductor plate may further include a first side surface adjacent to at least one first type doping region and a second side surface adjacent to at least one second-type doping region.

Another example semiconductor device may include a semiconductor plate. The semiconductor plate may have a first main surface and a second main surface opposite to the first main surface. The semiconductor plate may include at least one additional semiconductor layer deposited on the first main surface and/or the second main surface of the semiconductor plate.

Examples may also be directed to methods to manufacture semiconductor devices. An example method may include example method steps to form a semiconductor device. The example method steps to form the semiconductor device may include, among other things, providing a semiconductor substrate. The semiconductor substrate may have a first surface and a second surface opposite to the first surface. An additional method step may include depositing protecting layers on both the first surface and the second surface. Method steps may additionally include forming an array of first grooves on the first surface of the substrate and forming an array of second grooves on the second surface of the substrate. Each of the first grooves may be aligned with each of the second grooves. The array of first grooves may be separated from the array of second grooves. Further method steps may include performing the first-step doping on the sidewalls of the first grooves to form a first-type doping region on the sidewalls and performing the second-step doping on the sidewalls of the second grooves to form a second-type doping region on the sidewalls. Another method step may include removing a part of the substrate at the bottom of the first grooves and the second grooves, such that the first grooves and the second grooves are connected and merged into one groove, so as to form a vertical strip plate array of semiconductor plate devices.

Another example method may include example steps to form a semiconductor device. The example method steps to form a semiconductor device may include, among other things, providing a semiconductor substrate which may include a first surface and a second surface opposite to the first surface and depositing protecting layers on both the first surface and the second surface. Additional method steps may include forming an array of grooves in the substrate to form a vertical strip plate array of semiconductor plates. A further method step may include depositing at least another layer of semiconductor on the both surfaces of the semiconductor strip plates.

The present disclosure provides examples directed to a semiconductor device assembly. An example semiconductor device assembly may include a plurality of the semiconductor plate device. The first-doping regions of a semiconductor plate device may be electrically connected to the second-type doping region of one of its neighboring devices. The second-doping regions of a semiconductor plate device may be electrically connected to the first-type doping region of another one of its neighboring devices. The first-doping regions of a semiconductor plate device may be electrically connected to the first-doping regions of its neighboring devices. The second-type doping regions of a semiconductor plate device may be electrically connected to the second-doping regions of its neighboring devices.

In another aspect, the present disclosure further provides an example method for manufacturing a semiconductor assembly. The example steps to form a semiconductor device may include, among other things, separating the planar array of semiconductor plate devices from the substrate, placing the array of solar cell units onto a lower packaging encapsulation; wherein, the first surfaces of the solar cell units are in contact with the lower packaging encapsulation, connecting semiconductor plate devices, and forming a sealed package for the semiconductor plate device array.

These and other features and advantages will be apparent from a reading of the following detailed description and a review of the associated drawings. It is to be understood that both the foregoing general description and the following detailed description are explanatory and do not restrict aspects as claimed.

### BRIEF DESCRIPTION OF THE DRAWINGS

Other additional features, aspects and advantages of the present disclosure are made more evident according to perusal of the following detailed description of exemplary example(s) in conjunction with accompanying drawings:

FIG. 1 illustrates a cross-sectional view of a semiconductor plate device with the first-type doping regions and second-type doping regions on both surfaces;

FIG. 2 illustrate a cross-sectional view of a substrate with the first surface doped with the first-type doping and the second surface doped with the second-type doing, and protection layers on both the first surface and the second surface;

FIG. 3 illustrate a cross-sectional view of the substrate after forming an array of first grooves on the first surface of the substrate, and an array second grooves on the second surface of the substrate; wherein, each of the first groove is aligned with a second groove, and the depth of the first groove and the second groove is smaller than the thickness of the substrate;

FIG. 4 illustrate a cross-sectional view of the substrate after the first-step doping on the sidewalls of the first grooves so as to form a first-type doping region on the sidewalls thereof;

FIG. 5 illustrate a cross-sectional view of the substrate after the second-step doping on the sidewalls of the second grooves so as to form a second-type doping region on the sidewalls thereof;

FIG. 6 illustrates a cross-sectional view of the substrate after the removal of the parts of the substrates between the bottoms of the first groove and the second grooves, such that a first groove and a second groove are connected and merged into one groove, so as to form a vertical strip plate array of solar cell units.

FIG. 7 illustrates a cross-sectional view after removing the protecting layers at the first side surface and the second side surface of the semiconductor plates.

FIG. 8 illustrates a cross-sectional view of an array of semiconductor plates after packaging.

FIG. 9 illustrates a cross-sectional view of another semiconductor plate device with the first-type doping regions and second-type doping regions on both surfaces;

FIG. 10 illustrates a cross-sectional view of a substrate without the doping for both surfaces, and with protecting layers on both surfaces of the substrate;

FIG. 11 illustrates a cross-sectional view of a vertical strip plate array of semiconductor plate devices without doping on the both surfaces of the original substrate;

FIG. 12 illustrates a top view of a vertical strip plate array of semiconductor plate devices in the substrate;

FIG. 13 illustrates a vertical strip plate array of semiconductor plates with contacting layers deposited;

FIG. 14 illustrates a cross-sectional view of one example of semiconductor plate device assembly;

FIG. 15 illustrates a cross-sectional view of a semiconductor plate device with deposited semiconductor layers on both surfaces;

FIG. 16 illustrates a cross-sectional view of the substrate after forming an array of grooves in the substrate;

FIG. 17 illustrates a cross-sectional view of a vertical strip plate array of semiconductor plates after forming doping regions on both surfaces;

FIG. 18 illustrates a cross-sectional view of a vertical strip plate array of semiconductor plate with multiple semiconductor layers deposited on both surfaces, according to examples.

### DETAILED DESCRIPTION

As briefly described above, an increasing demand exists for ultra-thin solar devices with high efficiency and flexible contact arrangement made by a high-throughput fabrication process. An increasing demand exists for methods for solar and LED devices, as well. Device structure, methods, systems, and techniques, as briefly described above, include fabricating novel semiconductor plate devices, more specifically, include fabricating novel semiconductor plate solar devices and semiconductor plate LED devices. Examples disclosed herein provide manufacturing of semiconductor plate devices, operation of the semiconductor plate devices, and the semiconductor plate devices thereof.

In the following detailed description, references are made to the accompanying drawings that form a part hereof, and in which are shown by way of illustrations, specific examples or examples. These aspects may be combined, other aspects may be utilized, and structural changes may be made without departing from the spirit or scope of the present disclosure. The following detailed description is therefore not to be taken in the limiting sense, and the scope of the present disclosure is defined by the appended claims and their equivalents.

Generally, for the device structures, processes, and fabrication methods, those skilled in the art will appreciate that examples may be alternatively utilized practiced.

In the following detailed description, reference is made to the accompanying drawings, which form a part hereof. In the drawings, similar symbols typically identify similar components, unless context dictates otherwise. The illustrative examples described in the detailed description, drawings, and claims are not meant to be limiting. Other examples may be utilized, and other changes may be made, without departing from the spirit or scope of the subject matter presented herein. The aspects of the present disclosure, as generally described herein, and illustrated in the Figures, may be arranged, substituted, combined, separated, and designed in a wide variety of different configurations, all of which are explicitly contemplated herein.

Overall, the detailed examples of the present disclosure are to be described at length below, wherein examples of examples are illustrated in the appended drawings. It should be appreciated that examples described below in conjunction with the drawings are illustrative, and are provided for explaining the present disclosure, thus shall not be interpreted as a limit to the present disclosure.

Various examples or examples are provided here below to implement different structures and different method of the present disclosure. To simplify the disclosure of the present disclosure, descriptions of components and arrangements of specific examples are given below. The descriptions are merely illustrative and not intended to limit the present disclosure. Moreover, in the present disclosure, reference numbers and/or letters may be repeated in different examples. Such repetition is for purposes of simplicity and clarity, yet does not denote any relationship between respective examples and/or arrangements under discussion. Furthermore, the present disclosure provides various examples for various processes and materials. It is obvious for a person of ordinary skill in the art that other processes and/or materials may be alternatively utilized. It should be noted that the appended drawings might not be drawn to scale. Description of the typically known elements, processing techniques, and crafts are omitted from description of the present disclosure in order not to limit the present disclosure unnecessarily.

In the following detailed description, when one layer/element is described as, “on”, or “on top of”, or “over”, another layer/element. The above layer/component/element can be located directly on the other layer/component, or middle layers/elements can exist between them.

This disclosure is generally drawn to semiconductor plate devices, as well as systems, methods, and techniques to fabricate and operate such devices. The semiconductor plate devices may behave as solar cells or LED devices.

Briefly stated, technologies are generally described to include semiconductor plate devices, systems, and methods of manufacture with applications for solar cells and LED devices.

The present disclosure is intended to provide a semiconductor device and a method for manufacturing the same. Some examples of this semiconductor plate device may convert light into electricity and may be used as solar cells. Some examples of this semiconductor plate device may convert electricity into light and may be used as LED devices.

It may be desirable to use thin layer to form the solar cells. Due to the fragility of thin semiconductor sheet and potential efficiency loss, it is difficult to fabricate thin sheet solar cells, and more difficult to fabricate high efficiency thin solar cells, especially crystalline silicon based thin solar cells. The semiconductor plate devices described in the present disclosure may serve as ultra-thin solar cells with high efficiency. Due to its relative small feature size and the associated novel process method, the semiconductor device may overcome the fragility of thin semiconductor sheet devices and may result in high yield.

When the thickness of the solar cell unit is fairly thin, the photogenic charge carriers generated from the photo-electrical effect are present quite close to the PN junction, which facilitates the photogenic charger carriers to diffuse to the PN junction. Accordingly, as compared to the traditional solar cell unit, in the case the thickness of the solar cell unit is fairly thin, particularly when the thickness of the solar cell unit is less than 80 μm, the solar cell unit provided according to the present disclosure is capable of collecting effectively photogenic charger carriers, which may improve electrical current density of the solar cell and conversion efficiency of the solar cell.

The semiconductor plate device and its associated process may allow reduction of the thickness of the semiconductor plate of the solar cells at the meantime maintaining or improving performance of the solar cell unit. This may improve utility of the semiconductor plate material and may increase yield of the semiconductor plate manufacturing.

In addition, the present disclosure may provide a solar cell device that forms both contacts to a front surface or both contacts to a back surface or one contact to the front surface and one contact to the back surface. In another example, the solar cell device may form the contacts at the side surfaces, therefore providing the flexibility in contact arrangement. Thus, there may be no electrode positioned on the light absorption or emitting surface, which may avoid blocking light absorption of the solar cell or blocking light emitting in LED devices. In this way, the light absorption efficiency of the solar devices and light emitting efficiency of LED devices may be improved, which may improve conversion efficiency of the solar cell and LED devices.

The light may be absorbed or emitted from both main sides of the semiconductor plate device, which may make the semiconductor plate device a bi-facial device. This may greatly increase the light absorption efficiency and light emitting efficiency of the semiconductor plate device.

Most process steps for fabricating the semiconductor plate devices are carried out while the array of semiconductor plate devices are still attached to the substrate. So, just like a batch process, a large quantity of semiconductor plate devices may be fabricated at once, which is highly valuable to high cost process steps, such as semiconductor layer deposition. Furthermore, the high aspect ration of the thickness of the substrate to the thickness of the individual semiconductor plate, further enhance the process efficiency. Therefore, the process described here enables a high throughput process, and may greatly reduce the process cost.

The disclosed semiconductor plate devices may be presented in various forms, some examples of which are described below.

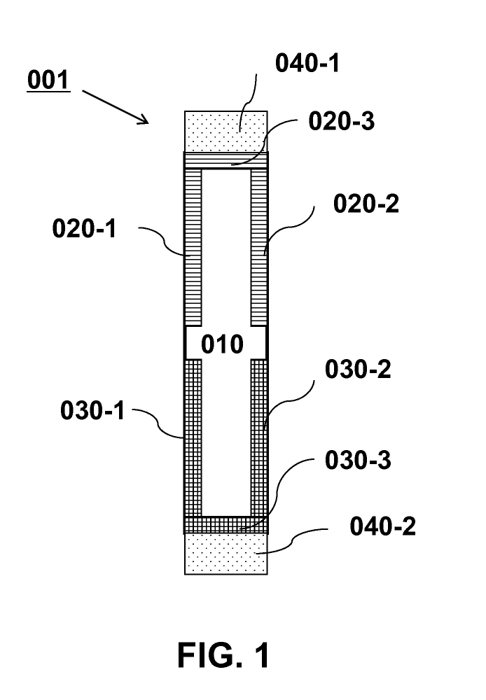

FIG. 1 illustrates a cross-sectional view of a semiconductor plate device with the first-type doping and second-type doping on main surfaces of the semiconductor plate device, according to at least some examples disclosed herein.

The semiconductor plate device 001 may include a semiconductor plate 010. The semiconductor plate 010 may be made from one or more from a set of materials: silicon (Si), germanium (Ge), or compound semiconductors. The semiconductor plate 010 may have a thickness between 5 μm to 500 μm. The semiconductor plate 010 may be un-doped, the first-type doped, or the second-type doped. In the semiconductor plate 010, the first-type doping regions, 020-1, 020-2 and 020-3 are formed on both of its main surfaces and at its first side surface, in this example, the top side surface. In the semiconductor plate 010, the second-type doping regions, 030-1, 030-2, and 030-3 are formed on both of its main surfaces and at its second side surface, in this example, the bottom side surface. The first-type doping regions, 020-1, 020-2 and 020-3, may be continuous. The second-type doping regions, 030-1, 030-2 and 030-3, may be continuous. At the first main surface, in this example, the left main surface, the first-type doped region 020-1 and the second-type doping region 030-1 are not in contact and may be separated from each other by a distance at least larger than 1 μm. At the second main surface, in this example, the right main surface, the first-type doping region 020-2, and the second-type doping region 030-2 are not in contact, and may be separated from each other, by a distance larger than 1 μm. The semiconductor plate 010 may also include protecting layers 040-1 and 040-2 at the first side surface and second side surface, respectively.

In the present disclosure, the first-type doping and second-type doping are of opposite polarity. It should be noted that the first-type doping and second-type doping definitions are interchangeable. The first-type doping may be n-type doping and the second-type doping may be p-type doping. In other examples, the first-type doping may be p-type doping and the second-type doping may be n-type doping.

In examples where the case the solar cell unit is fairly thin, the presence of photogenic charge carriers is quite close to the PN junction, which is favorable for diffusion of photogenic charger carriers to the PN junction. Accordingly, as compared to traditional solar cell units, in the case the solar cell unit is fairly thin, especially, when the thickness of the solar cell units is less than 80 μm, the solar cell units provided may be capable of effectively collecting photogenic charge carriers. This may improve electrical current density of the solar cell units and may also improve photo-electrical conversion efficiency.

The semiconductor plate device described in this example also provides contact flexibility, which may greatly reduce the contact shadowing in the solar cells. The semiconductor plate device may also absorb light from both of its sides, which may greatly enhance the light collection efficiency.

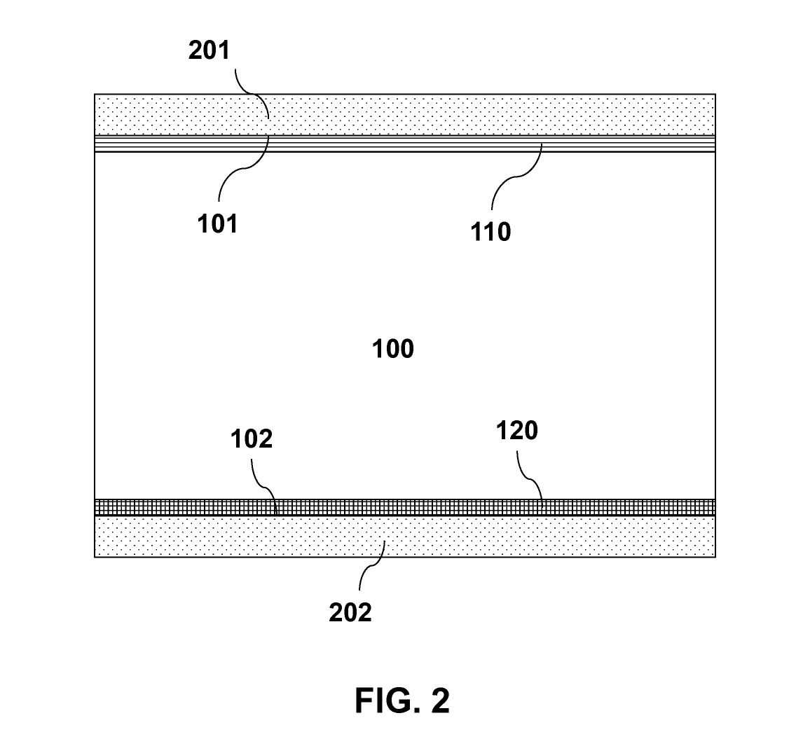

FIG. 2 illustrate a cross-sectional view of a substrate with the first surface doped with the first-type doping and the second surface doped with the second-type doing, and with protection layers on both the first surface and the second surface of the substrate, according to at least some examples disclosed herein.

Specifically, as shown in FIG. 2, a substrate 100 is provided. The substrate 100 may include a first surface 101, which is the top surface in FIG. 2, and a second surface 102, which is the bottom surface in FIG. 2. The second surface 102 is opposite to the first surface 101. The materials for the substrate 100 may be any one selected from a group including: monocrystalline Si, monocrystalline Ge, monocrystalline SiGe, poly Si, poly Ge, poly SiGe, amorphous Si, amorphous Ge, amorphous SiGe, compound semiconductors of groups III-V, compound semiconductors of groups II-VI, or combinations thereof.

In an example, the substrate 100 may be a semiconductor substrate and may include monocrystalline Si, monocrystalline Ge, or monocrystalline SiGe. The crystal orientation of the first surface 101 and the second surface 102 may be {110} or {112}. The thickness of the substrate 100 may be preferably less than 1 cm. The substrate 100 may be of a first-type doping, a second-type doping, or un-doped. The first-type doping and the second-type may be opposite to each other. For example, if the first-type doping is n-type doping, then the second-type doping is p-type doping. For example, if the first-type doping is p-type doping, then the second-type doping is n-type doping.

In this example, a first-type doping region 110 may be formed on the first surface 101 of the substrate 100 and a second-type doping region 120 may be formed on the second surface 102 of the substrate 100. The first-type doping region 110 and the second-type doping region 120 may be done by one of: spin-on doping diffusion, gas phase doping diffusion, ion implant, or other methods which are known to those having ordinary skill in the art.

Then, a first protection layer 201 and a second protection layer 202 may be formed on the first surface 101 and the second surface 102 of the substrate 100, respectively. The first protection layer 201 and a second protection layer 202 may be formed either individually or concurrently. The material for the first protection layer 201 and the second protection layer 202 may be any one selected from the group including: SiO₂, Si₃N₄, metal oxides, organic insulating materials, or combinations thereof. The first protection layer 201 and a second protection layer 202 may be in a single-tier structure or may be in a multi-tier structure, with a thickness desirable to the needs in practice.

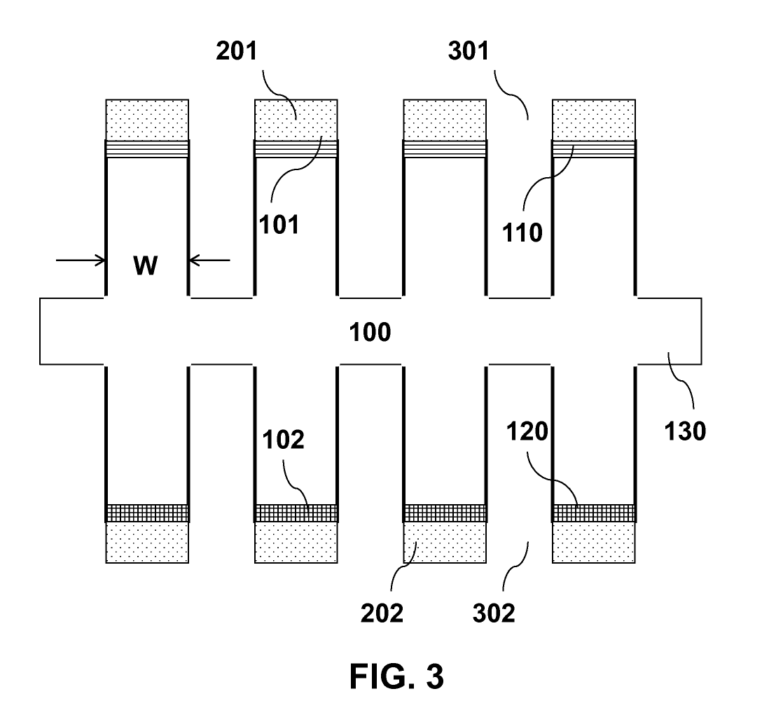

FIG. 3 illustrate a cross-sectional view of the substrate after forming an array of first grooves on the first surface of the substrate, and an array of second grooves on the second surface of the substrate, according to at least some examples disclosed herein.

An array of first grooves 301 may be formed on the first surface 101 of the substrate 100. In an example, the array of first grooves 301 includes at least two grooves. An array of second grooves 302, at least two, may be formed on the second surface 102 of the substrate 100. Each of the first grooves 301 may be aligned with a second groove on the array of second grooves 302 on the opposite side. The array of first grooves 301 are separated from the array of second grooves 302. The part 130 of the substrate is at the bottom of a first groove 301 and the bottom of an aligned second groove 302, which is neighboring. The combined depth of a first groove 301 and a second groove 302 is smaller than the thickness of the substrate 100.

Specifically, the first protection layer 201 and the second protection layer 202 may be patterned (e.g., through lithography process in addition to etching) to form a plurality of openings with predetermined space (not shown) on the first protection layer 201 and the second protection layer 202; this may expose the locations where the grooves to be formed on the substrate at subsequent steps. Then, the substrate 100 may be etched with the patterned first protection layer 201 and the second protection layer 202 functioning as masks, such that at least two of the first grooves 301 are formed on the first surface 101 of the substrate 100, and at least two of the second groove 302 are formed on the second surface 102 of the substrate 100, as shown in FIG. 3.

The first groove 301 and the second groove 302 may be opened toward/facing opposite directions. The second groove 302 is aligned to a neighboring first groove 301. The combined depth of the first groove 301 and the second groove 302 is less than the thickness of the substrate 100. In some examples, the depth of a first groove 300 and the depth of a second groove 302 are substantially equivalent. In some examples, the depth of the first groove 300 and the depth of the second groove 302 is less than a half of the thickness of the substrate 100.

In the example where the crystal orientation of the first surface 101 and the second surface 102 is {110} or {112}, the first groove 301 and the second groove 302 are formed by means of wet etching. Namely, the sidewall crystal orientation of the first groove 301 and the second groove 302 is made to be {111} by a method of controlling their opening directions. The substrate 100 may then be placed into a solution for etching. The solution may be, for example, KOH, TMAH, or EPD. The depth of the first groove 301 and the second groove 302 may be controlled by way of controlling the concentration of the solution, temperature, and the etching duration.

In other examples, the first groove 301 and the second groove 302 may be formed by means of dry etching, or a combination of wet etching and dry etching. In one example, the lateral distance between the closest sidewalls of two neighboring grooves of the first grooves 301 or two neighboring grooves of the second grooves 302 (denoted by w in FIG. 3) is preferably less than 500 μm. There may be a remaining part 130 between the bottom of a first groove 301 and the bottom of a neighboring groove of the second groove 302, and in one example, the thickness of the remaining part 130 is larger than 5 μm.

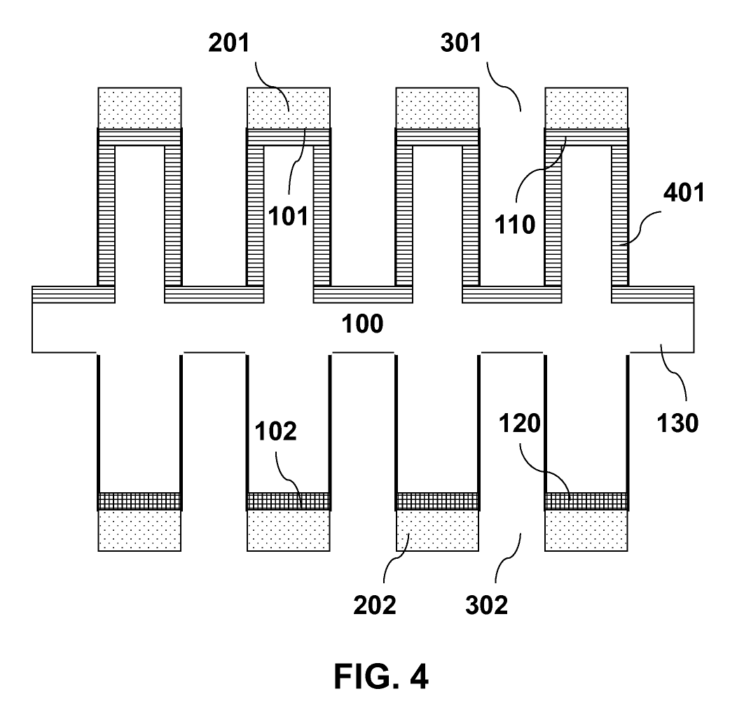

FIG. 4 illustrates a cross-sectional view of the substrate after the first-step doping on the sidewalls of the first grooves so as to form first-type doping regions on the sidewalls thereof, according to at least some examples disclosed herein.

In FIG. 4, the sidewalls of the first grooves 301 are doped to form the first-type doping region 401 on the sidewalls. Specifically, since it is merely necessary to perform doping to the sidewalls of the first groove 301, a covering layer (not shown) is formed on the sidewalls and at the bottom of the second groove 302 before doping. The material for the covering layer may be any one selected from a group including: SiO₂, Si₃N₄, and combinations thereof. The material for the covering layer may be different from the material for the second protection layer 202. The substrate 100 may be processed with semiconductor dopants by diffusion, CVD in-situ doping, or ion implantation, to form the first-type doping region 401 in the substrate 100 on both sides of the sidewalls of the first grooves 301, as shown in FIG. 4. If the dopants are p-type, then the first-type doping region 401 is a p-doping region. If the dopants are n-type, then the first-type doping region 401 is an n-doping region. The covering layer may be removed from the sidewalls and the bottom of the second groove 302 after completion of doping.

In other examples, the second surface 102 side of the substrate may be bonded with a wafer cap. The substrate 100 and the wafer cap may be placed into a diffusion furnace, such that the substrate 100 is doped by means of semiconductor dopants diffusion or CVD in-situ doping. Because the second surface 102 side of the substrate 100 is covered by the wafer cap, the first-type doping region 401 may be formed only on the both sides of the sidewalls and the bottom of the first groove 301.

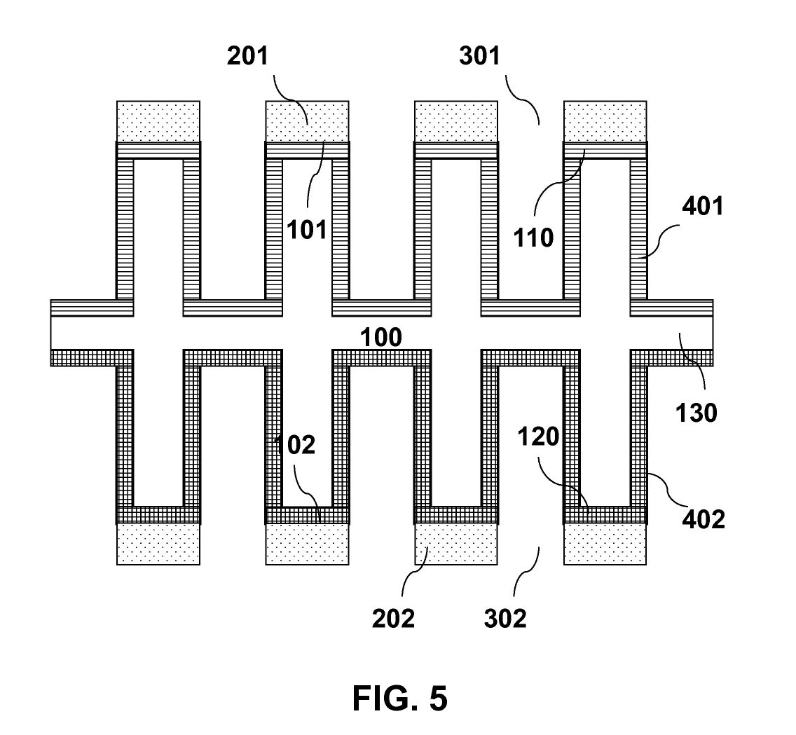

FIG. 5 illustrate a cross-sectional view of the substrate after the second-type doping on the sidewalls of the second grooves so as to form a second-type doping region on the sidewalls thereof, according to at least some examples disclosed herein.

The method and process steps to form the doping on the sidewalls of the second grooves is similar to form the doping on the sidewalls of the first grooves as described above, but with opposite doping type. In FIG. 5, the sidewalls of the second groove 302 are doped to form a second-type doping region 402 on the sidewalls. As doping needs to be performed on the sidewalls of the second groove 302, a covering layer (not shown) is formed on the sidewalls and at the bottom of the first groove 301 before doping. The materials for the covering layer may be any one selected from a group including: SiO₂, Si₃N₄, and combinations thereof, or any other materials as appropriate. The material for the covering layer may be different from the material for the first protection layer 201. The substrate 100 may be processed with semiconductor dopants by one of: diffusion, CVD in-situ doping, or ion implantation, so as to form the second-type doping region 402 in the substrate 100 on the sidewalls of the second groove 302, as shown in FIG. 5. The dopants used for doping the second groove 302 are in opposite polarity, as the dopant used for doping the first grooves 301. The covering layer may be removed from the sidewalls and the bottom of the first groove 301 after completion of doping of the second groove 302.

In another example method, the first surface 101 side of the substrate may be bonded with a wafer cap, then the substrate 100 and the wafer cap may be placed into a diffusion furnace, such that the substrate 100 is doped by means of semiconductor dopants diffusion or CVD in-situ doping. The first surface 101 side of the substrate 100 may be covered by the wafer cap. The second-type doping regions 402 may be formed only on the sidewalls and the bottom of the second groove 302.

In some examples, the first-type doping region 401 and the second-type doping region 402 may be heavy doping regions.

In some other examples, a transparent insulating layer or layers, a transparent conductive layer or layers, or a semiconductor layer or layers, or a combination thereof may be further formed in the sidewalls of the first groove 301 or the sidewalls of the second groove 302 by means of CVD, PVD, or ALD; this may further increase light absorption, reduce surface re-combination, or lower surface resistance. The material for the transparent insulating layer may be one or more of: Si₃N₄, SiO₂, metal silicide, or a combination thereof. The material for the transparent conductive layer may be TCO. TCO may include one or more of: SnO₂, In₂O₃, ZnO, ITO, CdO, Cd₂SnO₄, FTO, AZO, or combinations thereof. The semiconductor layers may be III-V compound semiconductors or II-VI compound semiconductors, such as GaAs, InP, or other semiconductors used in the field.

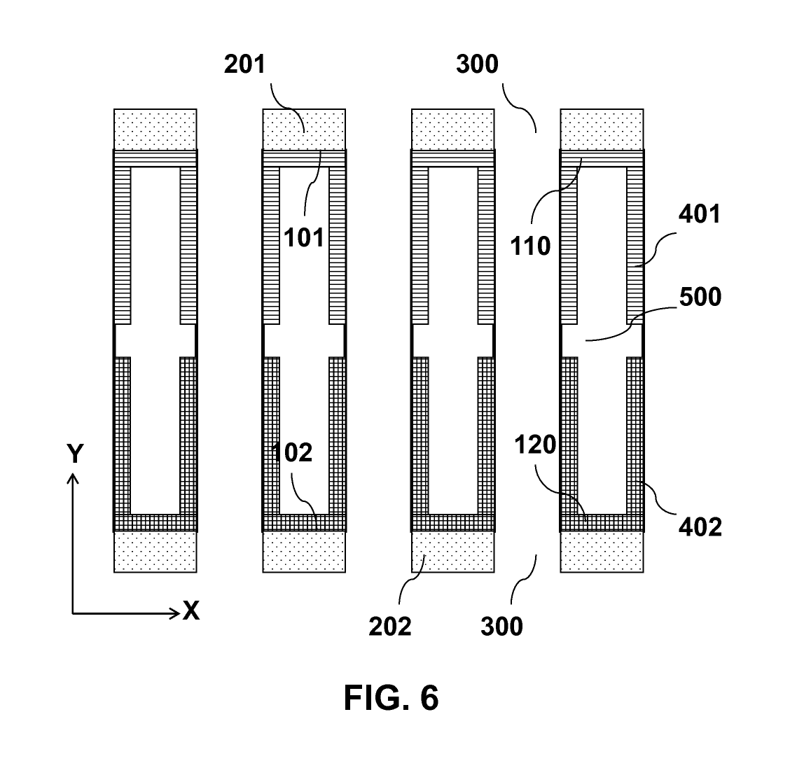

FIG. 6 illustrates a cross-sectional view of the substrate after the removal of the parts of the substrates between the bottoms of the first grooves and the second grooves, such that a first groove and a neighboring second groove are connected and merged into one groove, so as to form a vertical strip plate array of semiconductor plates, according to at least some examples disclosed herein.

In the example, the remaining part 130 in the substrates separating a first grooves 301 from a neighboring groove of the second groove 302 may be removed, such that a first groove 301 merges with the neighboring groove of the second groove 302 to become a first groove 300. The depth of the first groove 300 is substantially equivalent to the thickness of the substrate 100. The first groove 300 is formed from merging the first groove 301 with the neighboring groove of the second groove 302 after removing the remaining part 130.

Specifically, as shown in FIG. 6, the substrate 100 is etched continuously by means of wet etching and/or dry etching. Additionally, the part of the substrates 100 between the bottom of the first groove 301 and the second groove 302 are removed, such that the first groove 301 and the second groove 302 merges and become a new groove, which has a depth about the same as the thickness of substrate 100. The array of grooves is formed, so as to form semiconductor plates 500, where the semiconductor plates 500 may be held together by the remaining frame of substrate 100. In some examples, the semiconductor plates 500 may be in parallel. Along the Z direction, both ends of each semiconductor plates 500 may be connected to the remaining frame of substrate 100. The Z direction is perpendicular to the X-Y plane as denoted in FIG. 6.

In both main surfaces of the semiconductor plates 500, the first-doping region 401 and the second-doping region 402 are not continued, and rather separated. The distance between the first-doping region 401 and the second-doping region 402 on each main surface is defined by the thickness of the remaining part 130 in FIG. 5. The distance between the first-doping region 401 and the second-doping region 402 is substantially equivalent or slightly less than the thickness of the remaining part 130.

The substrates 100 between two neighboring grooves of the first groove 300 constitute the semiconductor plates 500. As shown in FIG. 6, the sidewalls of the first groove 300 form the surfaces of the semiconductor plates 500. The thickness of the semiconductor plates 500 is equivalent to the distance between its two main surfaces, which is preferably less than 500 μm. In this example, as shown in FIG. 6, the left surface of the semiconductor plates 500 is the first main surface, and the right surface of the semiconductor plates 500 is the second main surface. The first side surface of the semiconductor plates 500 is the first surface 101 of the substrate 100. The second side surface of the semiconductor plates 500 is the second surface 102 of the substrate 100. The thickness of the semiconductor plates 500 may be controlled by way of controlling lateral distance between the opening on the first protection layer 201 and the opening on the second protection layer 202, as described above. The semiconductor plates 500 may function as a solar cell, converting solar energy into electricity.

In examples, a transparent insulating layer may be further formed on the two main surfaces of the semiconductor plates 500 by means of CVD, PVD, or ALD. In this way, an increase in light absorption, a reduction in surface re-combination, or a lowering of surface resistance may be possible. The material for the transparent insulating layer may be one or more from a set of materials including: Si₃N₄, SiO₂, metal oxides, or a combination thereof.

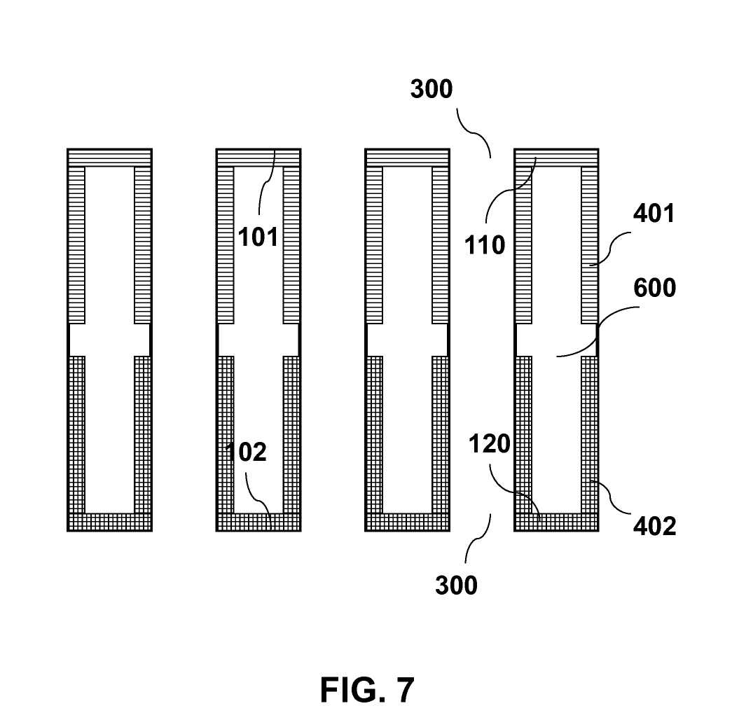

FIG. 7 illustrates a cross-sectional view after the removal of the protecting layers at both side surfaces of the array of semiconductor plates, according to at least some examples disclosed herein.

Specifically, the first protection layer 201 and the second protection layer 202 on the substrate 100 and on the semiconductor plates 500 may be removed by wet etching, dry etching, or a combination thereof. As shown in FIG. 7, after the removal of the first protecting layer 201 and the second protection layer 202, an array of semiconductor plates may be formed. The first side surface of semiconductor plates 600, which is also a part of the first surface of the substrate 100 and adjacent to the first-type doping region 401, may be exposed. As described above, a first-type doping region 110 may be formed at the first side surface of the semiconductor plates 600. The second side surface of the semiconductor plates 600, which is also a part of the second surface of the substrate 100 and adjacent to the second-type doping region 402, may be exposed. A second-type doping region 120 may be formed at the second side surface of the semiconductor plates 600.

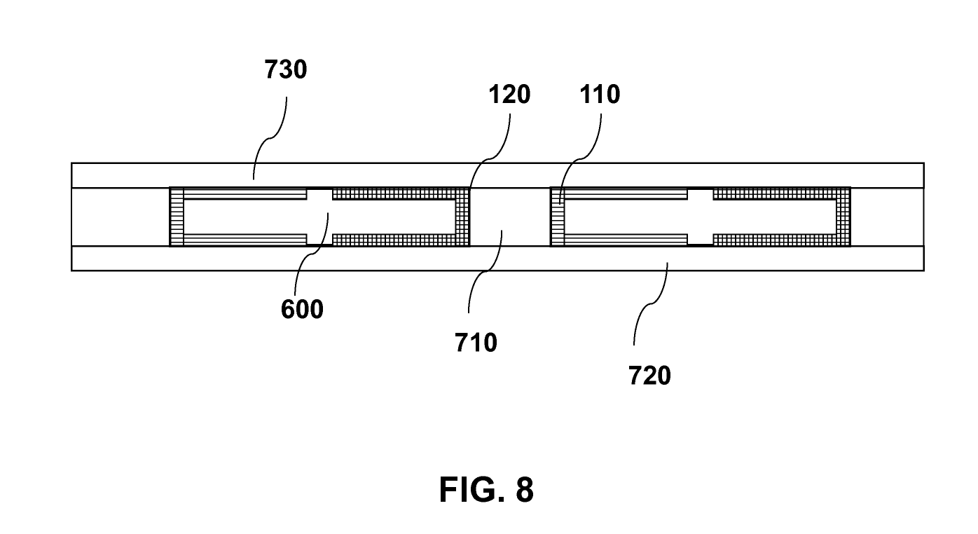

FIG. 8 illustrates a cross-sectional view of the array of semiconductor plates after packaging, according to at least some examples disclosed herein.

Specifically, the semiconductor plates 600 may be cut off by means of a laser beam or other cutting means from the substrate, such that the vertical strip plate array of semiconductor plates 600 may be separated from the substrate 100. The separated array of semiconductor plates 600 may be placed onto a lower packaging encapsulation 720. In one example, the vertical array of semiconductor plates 600 may become a planar array of semiconductor plates 600. In this example, one first main surface of a semiconductor plate 600 may be in contact with the lower packaging encapsulation 720. In this example, as shown in FIG. 8, the first-type doping region 110 of a semiconductor plates 600 is neighboring and connected to the second-type doping region 120 of a semiconductor plate 600, which may be located adjacent to the first-type doping region 110. A semiconductor plates 600 may be connected to another semiconductor plates 600, which may be located neighboring, by using conductive material 710 to connect the first side surface of a semiconductor plates 600 to the second side surface of another semiconductor plates 600. The conductive material 710 may be any one selected from a group including: Al, Cu, Ag, Au, Fe, Ni, Pb, Zn, Co, Ti, Mg, or combinations thereof. The conductive material 710 may electrically connect a semiconductor plate 600 with another semiconductor plates 600. In this example, the semiconductor plates 600 may be connected in series circuits. In other examples, the semiconductor plates 600 may be connected in parallel circuits or in the combination of series circuits and parallel circuits.

After the planar array of semiconductor plates 600 are placed onto the lower packaging encapsulation 720, the planar array of semiconductor plates 600 may be covered with upper packaging encapsulation 730 and may be sealed. The semiconductor plates 600 are positioned on one flat plane, so as to form a planar array of solar cells. In this example, the first main surface of the array of semiconductor plates 600 may contact the lower packaging encapsulation 720. The second main surface of semiconductor plates 600 may contact the upper packaging encapsulation 730. The material for the lower packaging encapsulation 720 and the upper packaging encapsulation 730 may be any one selected from the group including: glass, EVA, PVB, PET, HDPE, PVC, LDPE, PP, PS, or combinations thereof.

In another example, the top surface of the lower packaging encapsulation is not flat and may be in saw tooth or zig-zag form, so the semiconductor plates 600 may be arranged in parallel, but not on the same plane. In additional examples, the semiconductor plates 500, as shown in FIG. 5, may be used to form an array of solar cells.

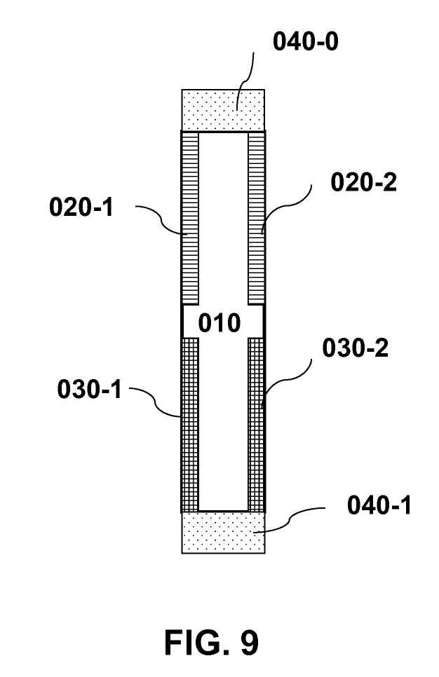

For another example, FIG. 9 illustrates a cross-sectional view of another novel semiconductor plate device with the first-type doping and second-type doping on both surfaces, according to at least some examples disclosed herein.

The semiconductor plate device described in FIG. 9 is very similar to the semiconductor plate devices described in FIG. 1, except that the first-type doping region 020-3 and the second-type doping region 030-3 shown in FIG. 1 are removed. Some of the detailed description for this semiconductor plate device may be referred to the description for the semiconductor plate devices described in FIG. 1.

In the semiconductor plate 010, the first-type doping regions, 020-1 and 020-2, are formed on both of its main surfaces, respectively, and the second-type doping regions 030-1 and 030-2, are formed on both of its main surfaces, respectively. On each main surface, the first-type doping region is separated from the second-type doping region.

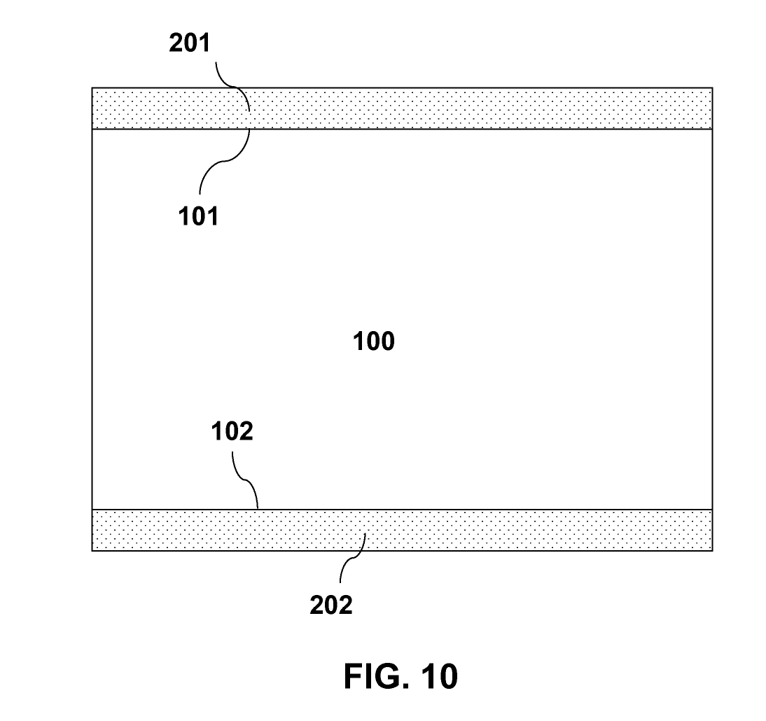

FIG. 10 illustrates a cross-sectional view of a substrate without the doping for both of its surfaces, and with protecting layers on both surfaces, according to at least some examples disclosed herein.

Starting from a substrate 100, as shown in FIG. 10, the substrate 100 may include a first surface 101, which may be the top surface in FIG. 10. The substrate 100 may also include a second surface 102, which is the bottom surface in FIG. 10. The second surface 102 is opposite to the first surface 101. The material for the substrate 100 is similar to the choice of the substrate 100 described in FIG. 2. In an example, a substrate 100 of the semiconductor may include monocrystalline Si, monocrystalline Ge, or monocrystalline SiGe. In an example, the crystal orientation of the first surface 101 and the second surface 102 is {110} or {112}. The thickness of the substrate 100 is preferably less than 1 cm. The substrate 100 may be of first-type doping, second-type doping, or un-doped. In an example, the first-type doping and the second-type doping may be opposite to each other; in other words, if the first-type doping is n-type, then the second-type doping is p-type. In another example, if the first-type doping is p-type, then the second-type doping is n-type.

Then, a first protection layer 201 and a second protection layer 202 are formed on the first surface 101 and the second surface 102 of the substrate 100, respectively. The first protection layer 201 and a second protection layer 202 may be formed either individually or concurrently. The material for the first protection layer 201 and a second protection layer 202 may be any one selected from the group including: SiO₂, Si₃N₄, metal oxides, organic insulating materials, or combinations thereof. The first protection layer 201 and a second protection layer 202 may be in a single-tier structure or may be in a multi-tier structure, with a thickness desirable to the needs in practice.

In one example, following the process steps described in FIGS. 3, 4, 5, and 6, an array of the semiconductor plates 510 may be fabricated. The semiconductor plates 510 may be a vertical semiconductor plate.

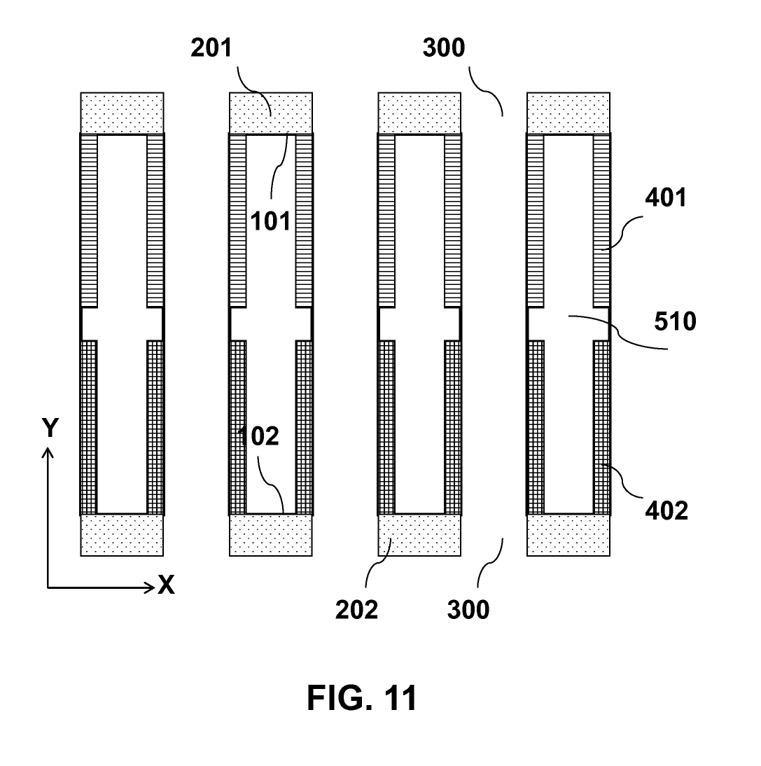

FIG. 11 illustrates a vertical strip plate array of semiconductor plates without doping for the both surfaces of the original substrate, according to at least some examples disclosed herein.

Similar to the structures and process steps described in FIG. 6, an array of grooves may include the first groove 300 and may be formed in the substrate 100, so as to form the semiconductor plates 510. The semiconductor plates 510 may be a vertical strip plate array. The depth of the first groove 300 may be substantially the same as the thickness of the substrate 100.

Specifically, as shown in FIG. 11, the substrate 100 may be etched continuously by means of wet etching and/or dry etching, and the first groove 300, which has a depth substantially the same as the thickness of substrate 100, may be formed. The array of grooves that includes the first groove 300 is formed, so as to form semiconductor plates 510. The semiconductor plates 510 may be parallel. The semiconductor plates 510 are held together by the remaining frame of substrate 100. Along the Z direction, the semiconductor plates 510 at both ends may be connected to the remaining frame of substrate 100. The Z direction is perpendicular to the X-Y plane as denoted in FIG. 11. The substrates 100 between the two neighboring grooves 300 constitute the semiconductor plates 510. As shown in FIG. 11, the sidewalls of the first grooves 300 form the surfaces of the semiconductor plates 510. Doping regions exist on the sidewalls of the first groove 300 or on both main surfaces of the semiconductor plates 510.

As shown in FIG. 11, the semiconductor plate 510 has a first main surface, the left main surface, and a second main surface, the right main surface. The thickness of the semiconductor plates 510 is equivalent to the distance between its two main surfaces, which preferably is less than 500 μm. The thickness of the semiconductor plates 510 may be controlled by way of controlling a lateral distance between the opening on the first protection layer 201 and the opening on the second protection layer 202, as described above. The semiconductor plates 510 may function as a solar cell to converting solar energy into electricity.

In each main surface of the semiconductor plates 510, the first main surface and the second main surface, there are two separated doping regions. The first-type doping region 401 and the second-type doping region 402 are not continued, and rather separated. In one example, the distance between the first-doping region 401 and the second-doping region 402 is equivalent to the thickness of the remaining part 130 as shown in FIG. 5. In additional examples, the distance between the first-doping region 401 and the second-doping region 402 is slightly less than the thickness of the remaining part 130. The semiconductor plates 510 is similar to the semiconductor plates 500 described in FIG. 6, except that the first-type doping layer 110 and the second-type doping region 120 as in semiconductor plates 500 are nonexistent.

In some examples, a transparent insulating layer may be further formed on the two surfaces of the semiconductor plates 510 by means of CVD or PVD. In this way, light absorption may be increased, surface re-combination may be reduced, and/or surface resistance may be lowered. The material for the transparent insulating layer may include one or more of: Si₃N₄, SiO₂, metal oxides, or a combination thereof.

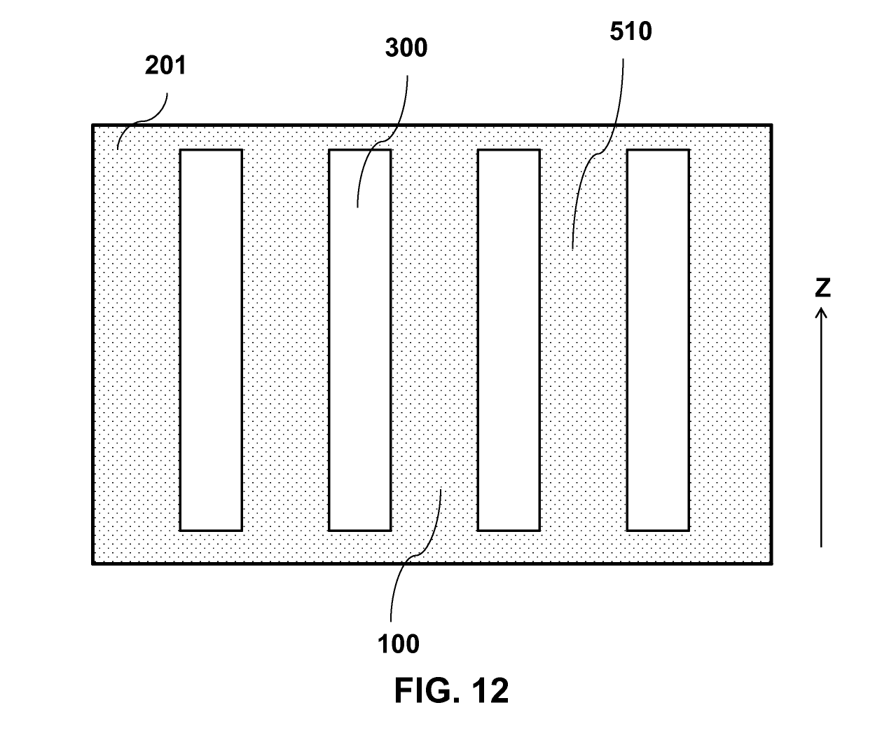

FIG. 12 illustrates a top view of a vertical array of semiconductor plate devices in the substrate, according to at least some examples disclosed herein.

FIG. 12 is the top view of the same structure presented in FIG. 11. The first surface of substrate 100 is covered by the first protection layer 201. One semiconductor plates 510 is separated from another by an array of grooves that includes the first grooves 300. Moreover, along the Z direction as denoted in FIG. 12, the two ends of the semiconductor plates 510 are connected to the substrate 100.

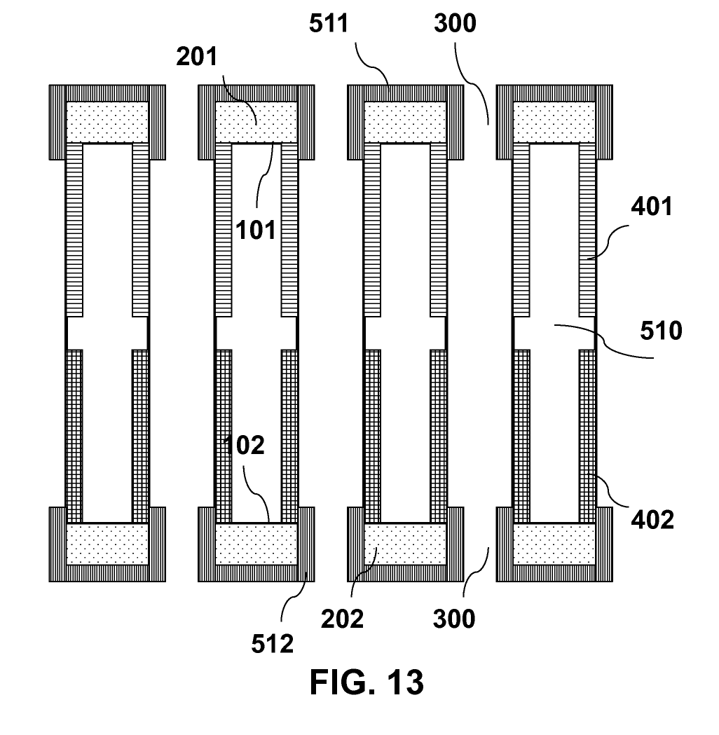

FIG. 13 illustrates a vertical strip plate array of semiconductor plate devices with contacting layers deposited to both ends, according to at least some examples disclosed herein.

Specifically, as shown in FIG. 13, contacting layers 511, 512 may be applied to cover the first protection layer 201 and the second protection layer 202 on semiconductor plates 510, respectively. The contacting layer 511 may also be connected and deposited on part of the surfaces of the first-type doping region in the semiconductor plates 510. The contacting layer 512 may also be connected and deposited on part of the surfaces of the second-type doping region in the semiconductor plates 510. The contacting layer 511 and the contacting layer 512 may be separated from each other. The width of the first-type doping region covering with the contacting layer 511 is preferably less than 500 μm. The width of the second-type doping region covering with the contacting layer 512 is also less than 500 μm.

The contacting layers 511, 512 may be deposited by means of angular deposition or other means, as appropriate. The material for the contacting layers 511, 512 may include any one selected from the group including: Ni, Pt, Co, Al, Cr, Cu, Ag, Au, Fe, Pb, Zn, Ti, Mg, Sn, or combinations thereof. The contacting layers 511, 512 may be single layer structures or multiple-layer structures.

In other examples, the contacting layers 511, 512 may be formed by way of dip coating capable of depth controlling. Namely, the vertical strip plate array of solar cell units is dipped into metal slurry such that the metal slurry is present on surface of the first-type doping region 401 or the second-type doping region 402 by way of controlling the dipping depth. After the metal slurry has cured, the contacting layers 511, 512 are formed on the surfaces of the first-type doping region 401 or the second-type doping region 401, respectively. The metal slurry is preferably any one selected from a group including: Ni slurry, Co slurry, Pt slurry, Al slurry, Cr slurry, Cu slurry, Ag slurry, Au slurry, Fe slurry, Pb slurry, Zn slurry, Ti slurry, Mg slurry, Sn slurry, or combinations thereof. Annealing treatment is carried out such that the contacting layers 511, 512 are formed on the surface of the first-type doping region 401 and the second-type doping region 402, respectively.

In one example, instead of removing the first protecting layer 201 and the second protecting layer 202, as shown in FIG. 7, the semiconductor plates 500 in FIG. 6 may follow the process steps described in FIG. 13 to form contacting layers, and following the process steps described below to be packaged.

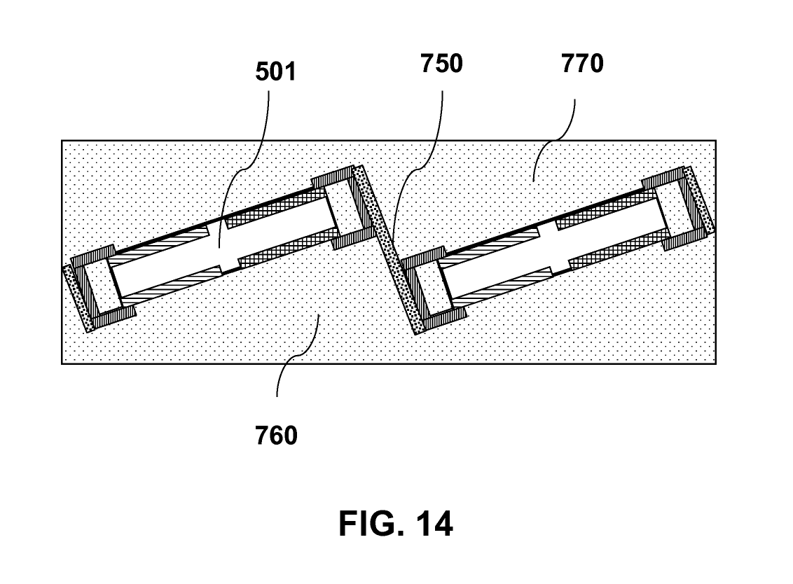

FIG. 14 illustrates a cross-sectional view of an array of semiconductor plates after packaging, according to at least some examples disclosed herein.

The packaging process is essentially similar to the process described in FIG. 8. In the example described in FIG. 14, the top surface of the lower packaging encapsulation 760 is not flat. After an array of semiconductor plates 510 is separated from the substrate 100, the separated array of the semiconductor plates 510 may be placed onto a lower packaging encapsulation 760 with the first main surface of the semiconductor plates 510 in contact with the lower packaging encapsulation 760.

In one example, the contact layer 511 contacting the first-type doping region 110 of a semiconductor plate 510 is neighboring and connected to the contact layer 512 of another neighboring semiconductor plate. The contact layer 512 is contacting the second-type doping region 120 of the neighboring semiconductor plate 510. A contacting bar 750 may be used to connect semiconductor plates 510. The contacting bar 750 is connected to the contact layer 511 of a semiconductor plate 510 and the contact layer 512 of another neighboring semiconductor plate 510, which may be located adjacent. The contacting bar 750 may be any one selected from a group including: Al, Cu, Ag, Au, Fe, Ni, Pb, Zn, Co, Ti, Mg, or combinations thereof. The contacting bar 750 electrically connects a semiconductor plate 510 with another semiconductor plates 510 which may be located neighboring. In this example, the semiconductor plates 510 are connected in series circuit. In another example, the semiconductor plates 510 may be arranged in parallel circuit or a combination of series circuit and parallel circuit.

In one example, the semiconductor plates 510, which may be a planar array, may be placed onto the lower packaging encapsulation 760. In this example, as shown in FIG. 14, the top surface of the lower packaging encapsulation is not flat and is in a saw tooth or Zig-Zag shape, so the semiconductor plates 510 are in parallel, but not on the same plane. The semiconductor plates 510 may be covered with upper packaging encapsulation 770 and the second main surface of the semiconductor plates 510 contacts with the upper packaging encapsulation 770. The packaging encapsulation may be heated and sealed. The material for the lower packaging encapsulation 760 and the upper packaging encapsulation 770 may be any one selected from the group including: glass, EVA, PVB, PET, HDPE, PVC, LDPE, PP, PS, or combinations thereof.

In another example, the semiconductor plates 510 may also be arranged similar to the semiconductor plates 600 shown in FIG. 8, with the semiconductor plates 510 on a flat surface.

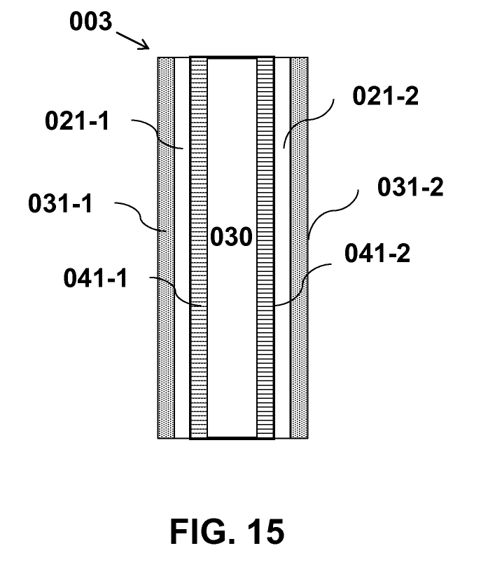

In yet another example, FIG. 15 illustrates a cross-sectional view of a semiconductor plate device with deposited semiconductor layers on both surfaces, according to at least some examples disclosed herein.

This semiconductor plate device 003 may include a semiconductor plate 030. The semiconductor plate 030 may be made from one or more from a set of materials: silicon (Si), germanium (Ge), or compound semiconductors. The semiconductor plate 030 may have a thickness between 5 μm to 500 μm. The semiconductor plate 030 may be un-doped, first-type doped, or second type doped. In the semiconductor plate 030, on both main surfaces, there may be the doping regions, 041-1 and 041-2. The doping regions may be the first-type or the second-type. The doping regions on both surfaces may have the same type or opposite polarity. On either of the main surfaces of the semiconductor plate 030, there is at least one layer of semiconductor deposited.

In one example, as shown in FIG. 15, a semiconductor layer 021-1, 021-2 is deposited on both main surfaces of the semiconductor plate 020. Another semiconductor layer 031-1, 031-2 is deposited over the semiconductor layer 021-1 and 021-2. In an example, the semiconductor layer 021-1, 021-2 and the other semiconductor layer 031-1, 031-2 is in opposite polarity. Additionally, the semiconductor layer 021-1, 021-2 and the doping layer 041-1 and 041-2 may also in opposite polarity. For example, if the doping layer 041 is the first-type doping, then the semiconductor layer 021-1, 021-2 is the second-type doping and the semiconductor layer 031-1, 031-2 is the first-type doping. The doping regions 041-1 and 041-2 may have different doping type as the semiconductor plate 030. In other examples, the other arrangements for the doping types for these layers may also be feasible to make the device function. One or more deposited semiconductor layer can be un-doped, as well. In some examples, the doping regions 041-1 and 041-2 may be skipped.

Starting from a substrate, similar to the substrate shown in FIG. 10, a substrate 100 may be provided. The substrate 100 may include first surface 101 and a second surface 102. A first protecting layer 201 may be deposited on the first surface 101 and a second protecting layer 202 may be deposited on the second surface 102.

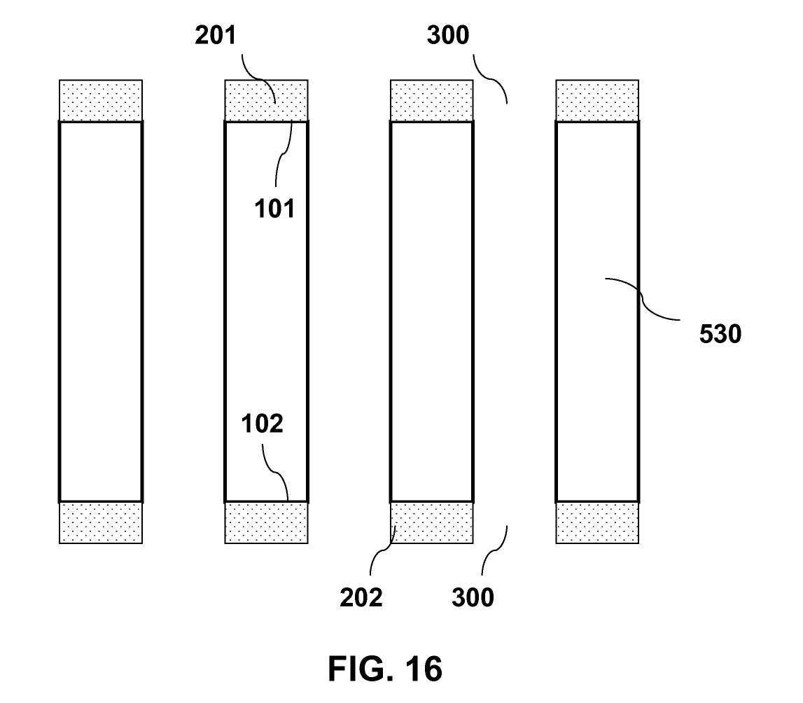

FIG. 16 illustrates a cross-sectional view of the substrate after forming an array of grooves in the substrate, according to at least some examples disclosed herein.

An array of grooves includes the first groove 300, at least two, may be formed in the substrate 100. Each of the grooves in the first grooves 300 is in parallel to each other. The depth of the grooves in the array of the first groove 300 is substantially the same as the thickness of the substrate 100.

Specifically, the first protection layer 201 or the second protection layer 202 are patterned. The patterning may occur through a lithography process in addition to etching. The patterning may form a plurality of openings with a predetermined space (not shown) on the first protection layer 201 or the second protection layer 202. To speed up the process, the openings may be formed on both the first protection layer 201 and the second protection layer 202 simultaneously, and each opening on the first protection layer 201 may be aligned with an opening on the second protection layer 202, in an opposite direction. The substrate 100 may be etched with the patterned first protection layer 201 or the second protection layer 202, functioning as masks.

In the example where the crystal orientation of the first surface 101 and the second surface 102 is {110} or {112} the first groove 300 may be formed by means of wet etching. Namely, the sidewall crystal orientation of the first groove 300 may be made to be {111} by way of controlling their opening directions. The substrate 100 may then be placed into a solution, such as KOH, TMAH, or EPD, for etching. In other examples, the first groove 300 may be formed by means of dry etching, or combination of wet etching and dry etching. In one example, the lateral distance between the closest sidewalls of the two neighboring grooves 300 may be less than 500 μm. A vertical array of semiconductor plates 530 may be formed.

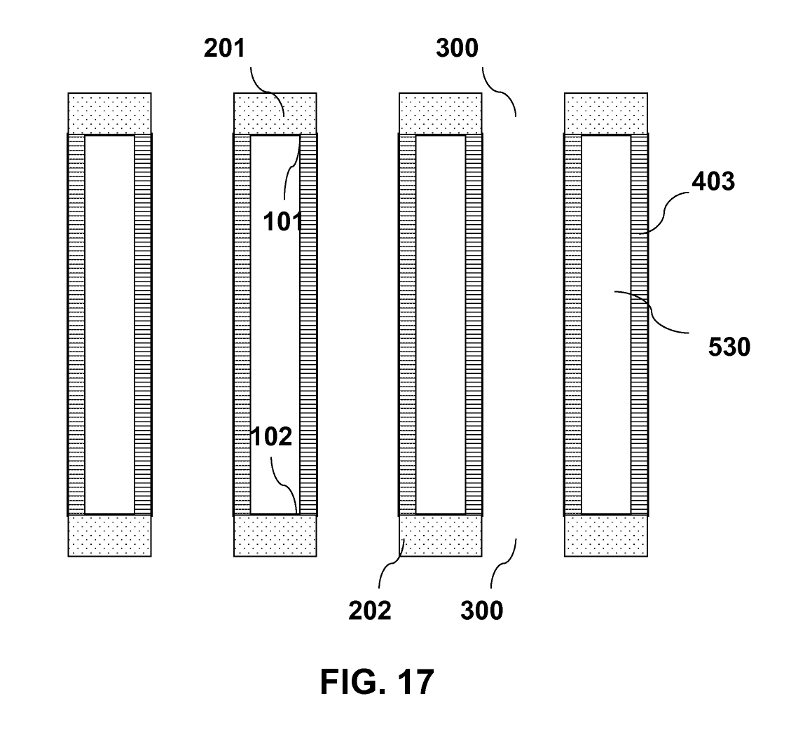

FIG. 17 illustrates a cross-sectional view of a vertical array of semiconductor plates after forming doping regions on both main surfaces, according to at least some examples disclosed herein.

Specifically, a doping layer 403 may be formed on the sidewalls of the first grooves 300, which may also be the surfaces of the semiconductor plate 530. The substrate 100 may be processed with semiconductor dopants diffusion, CVD in-situ doping, or ion implantation, to form the first-type doping region 403 on both main surfaces of semiconductor plate 530. In one example, the first-type doping region 403 may have different polarity from the substrate 100. If the substrate includes the first-type doping, the doping layer 403 may include the second-type region. The doping type of the doping layer 403 may also depend on the semiconductor layers deposited over it. In some examples, the doping layer 403 may have the same polarity as the substrate 100. In some other example, the doping layer 403 may be skipped.

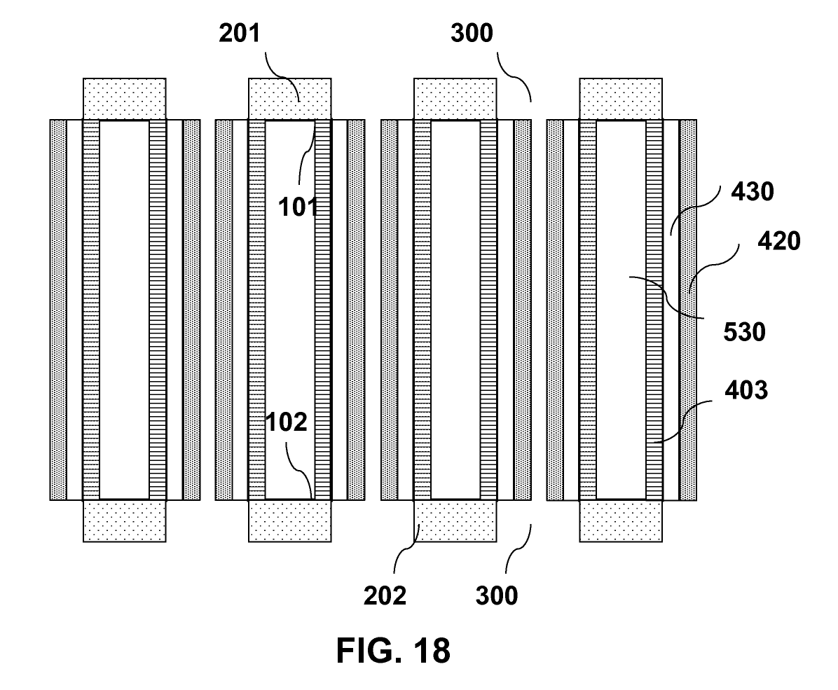

FIG. 18 illustrates a cross-sectional view of an array of semiconductor plate with multiple semiconductor layers deposited on both main surfaces, according to at least some examples disclosed herein.

At least one layer of semiconductor layer may be deposited on both main surfaces of the semiconductor plate 530. Specifically, by CVD, MBE, ALD, sputtering, or other methods, more than one layer of semiconductor layer can be deposited on the sidewalls of the array of first grooves 300. The semiconductor materials may include one or more from a set of: silicon (Si), germanium (Ge), III-V compound semiconductors, or II-VI compound semiconductors, among others. Examples of the compound semiconductor substrates include, among others, silicon-germanium (SiGe), gallium arsenide (GaAs), gallium antimonide (GaSb), aluminum arsenide (AlAs), indium monoarsenide (InAs), indium phosphide (InP), gallium nitride (GaN), silicon carbide (SiC), indium gallium arsenide (InGaAs), indium antimonide (InSb), and indium gallium antimonide (InGaSb). Each deposited semiconductor layer may be doped or un-doped.

In some examples, the doping types of two adjacent semiconductor layers may in opposite polarity. If one semiconductor layer is the first-doping type, then the adjacent neighboring layers are the second-type doping. Each semiconductor layer may have a thickness between 1 nm to 100 μm. As shown in FIG. 18, a semiconductor layer 430 may be deposited on both main surfaces of the semiconductor plate 530. Another layer of semiconductor 420 may be deposited on top of the semiconductor layer 430. In one example, the semiconductor layer 420 and the other semiconductor layer 430 are in opposite polarity. Also, the semiconductor layer 430 and the doping layer 403 may be also in opposite polarity, such as if the doping layer 403 is the first-type doping, then the semiconductor layer 430 may be the second-type doping and the other semiconductor layer 420 may be the first-type doping. In some other examples, the semiconductor layer 420 or 430 may be undoped.

In some examples, the first protection layer 201 and the second protection layer 202 may be removed. The electrodes may be connected to the exposed un-doped region of the first surface 101 of substrate on the semiconductor plate 530 (the first side surface) or the exposed un-doped region of the second surface 102 of substrate on the semiconductor plate 530 (the second side surface). The main surfaces of the semiconductor plate 530 may be connected to the electrodes with the same polarity.

In some examples, the deposited semiconductor layers on one main surface of semiconductor plate 530 may be removed and the deposited semiconductor layers may be formed only on one main surface side of the semiconductor plate 530. The removal of the semiconductor layers on one main surface may be done after separating the semiconductor plate from the substrate. Thus, each of the two main surfaces may be connected to an electrode, and the two electrodes may have different polarity.

In some examples, a transparent insulating layer, a transparent conductive layer, or a combination thereof may be further formed on the main surfaces of the semiconductor plate 530 on top the deposited semiconductor layers by means of CVD or PVD. In this way, light absorption may be increased, surface re-combination may be reduced, and/or surface resistance may be lowered. The material for the transparent insulating layer may include one or more of: Si₃N₄, SiO₂, metal silicide, or a combination thereof. The material for the transparent conductive layer may be TCO, which may include one or more of: SnO₂, In₂O₃, ZnO, ITO, CdO, Cd₂SnO₄, FTO, AZO, or combinations thereof.

After separating from the substrate 100, the semiconductor plate 530 may be packaged in an array or may be packaged individually or divided into parts to be packaged. The packaged device may serve as solar cell. In other examples, the semiconductor plate 530 may serve as LED device.

In the above description, the examples used n-type doping and p-type doping. It should be understood to those skilled in the art that there can be different types of doping, for example, in the above examples, the n-type doping and the p-type doping, which may be interchanged.

In the above description, the composition of the layers and the etching of the details of the detailed description are not made. The skilled person will appreciate that, through various techniques, formation of the desired shape of a layer, region, and the like, is possible. Further, to form the same structure, those skilled in the art may devise a method, as described above, that is not exactly the same way. Further, although the above examples are separately described, this does not mean that the implementation of the various examples of the measures may not be combined to an advantage.

The present disclosure is not to be limited in terms of the particular examples described in this application, which are intended as illustrations of various aspects. Many modifications and variations may be made without departing from the spirit and scope of the description. Functionally equivalent methods and apparatuses within the scope of the disclosure, in addition to those enumerated herein, will be possible from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, systems, or components, which can, of course, vary. It is also to be understood that the terminology used herein is for the purpose of describing particular examples only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. The use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations).

Furthermore, in those instances where a convention analogous to “at least one of A, B, and C, etc.” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Although the exemplary examples and their advantages have been described at length herein, it should be understood that various alternations, substitutions and modifications may be made to the examples without departing from the spirit of the present disclosure and the scope as defined by the appended claims. As for other examples, it may be easily appreciated by a person of ordinary skill in the art that the order of the process steps may be changed without departing from the scope of the present disclosure.

In addition, the scope, to which the present disclosure is applied, is not limited to the process, mechanism, manufacture, material composition, means, methods and steps described in the specific examples in the specification. According to the disclosure of the present disclosure, a person of ordinary skill in the art should readily appreciate from the disclosure of the present disclosure that the process, mechanism, manufacture, material composition, means, methods and steps currently existing or to be developed in future, which perform substantially the same functions or achieve substantially the same as that in the corresponding examples described in the present disclosure, may be applied according to the present disclosure. Therefore, it is intended that the scope of the appended claims of the present disclosure include these process, mechanism, manufacture, material composition, means, methods or steps.

While various aspects and examples have been disclosed herein, other aspects and examples will be apparent to those skilled in the art. The various aspects and examples disclosed herein are for purposes of illustration and are not intended to be limiting, with the true scope and spirit being indicated by the following claims.

What is claimed is:

1. A semiconductor device comprising:
a semiconductor plate comprising:
a first main surface comprising:
at least one first-type doping region and at least one second-type doping region; and
a second main surface comprising:
at least one other first-type doping region and at least one other second-type doping region;
a first side surface adjacent to at least one first-type doping region; and
a second side surface adjacent to at least one second-type doping region.

2. The semiconductor device of claim 1, wherein the semiconductor device is configured to one from a set of: convert light into electricity and convert electricity into light.

3. The semiconductor device of claim 1, wherein the at least one first-type doping region on the first main surface is separated from the at least one second-type doping region on the first main surface and the at least one other first-type doping region on the second main surface is separated from the at least one other second-type doping region on the second main surface.

4. The semiconductor device of claim 1, wherein the at least one first-type doping region on the first main surface is directly opposite to the at least one other first-type doping region on the second main surface and the at least one second-type doping region on the first main surface is directly opposite to the at least one other second-type doping region on the second main surface.

5. The semiconductor device of claim 1, wherein the semiconductor plate device further comprises:
a protection layer on the first side surface; and
another protection layer on the second side surface.

6. The semiconductor plate device of claim 1, wherein the semiconductor plate device further comprises:
an electrically contacting layer contacting part of the at least one first-type doping region and the at least one other first-type doping region; and
another electrically contacting layer contacting part of the at least one second-type doping region and the at least one other second-type doping region.

7. The semiconductor device of claim 1, wherein the semiconductor plate device further comprises:
at least one further first-type doping region on the first side surface; and
at least one further second-type doping region on the second side surface.

8. The semiconductor device of claim 1, wherein:
the at least one first-type doping region and the at least one other first-type doping region electrically connect, respectively, to at least one second-type doping region and at least one other second-type doping region of a neighboring semiconductor plate and the at least one second-type doping region and the at least one other second-type doping region electrically connect, respectively, to at least one first-type doping region and at least one other first-type doping region of another neighboring semiconductor plate; or
the at least one first-type doping region and the at least one other first-type doping region electrically connect, respectively, to the at least one first-type doping region and the at least one other first-type doping region of the neighboring semiconductor plate and the at least one second-type doping region and the at least one other second-type doping region electrically connect, respectively, to the at least one second-type doping region and the at least one other second-type doping region of the other neighboring semiconductor plate.

9. The semiconductor device of claim 8, wherein the semiconductor plate and the other semiconductor plate are parts of semiconductor devices in parallel and are not on the same plane.

10. A semiconductor device comprising:
a semiconductor plate comprising:
a first main surface and a second main surface opposite to the first main surface; and
at least one semiconductor layer deposited on at least one of the first main surface and the second main surface.

11. The semiconductor device of claim 10, wherein the semiconductor device is configured to one from a set of: convert light into electricity and convert electricity into light.

12. The semiconductor device of claim 10, wherein
a first semiconductor layer is deposited on the first main surface and/or the second main surface; and
a second semiconductor layer is deposited on the first semiconductor layer; and
the first semiconductor layer and the second semiconductor layer include dopants of opposite polarity.

13. The semiconductor device of claim 10, wherein the semiconductor plate comprises:
at least one doping region on the first main surface and at least one other doping region on the second main surface.

14. The semiconductor device of claim 10, wherein one or more of: transparent insulating layers and transparent conducting layers on top of at least part of one or more of: the first main surface and the second main surface.

15. A method to manufacture a semiconductor device, the method comprising:
providing a semiconductor substrate, wherein the semiconductor substrate comprises a first surface and a second surface opposite to the first surface;
depositing protecting layers on the first surface and the second surface;
forming an array of grooves in the substrate to form a vertical array of semiconductor plates;

16. The method of claim 15, further comprising:
forming a first-type doping layer of the first surface of the substrate; and
forming a second-type doping layer on the second surface of the substrate.

17. The method of claim 15, further comprising,
forming an array of first grooves on the first surface of the semiconductor substrate;
forming an array of second grooves on the second surface of the semiconductor substrate, wherein each of the array of first grooves is aligned with each of the array of second grooves, and wherein the array of first grooves are separated from the array of second grooves;
performing doping on sidewalls of the array of first grooves to form a first-type doping region on the sidewalls of the array;
performing doping on sidewalls of second grooves to form a second-type doping region on the sidewalls of the second grooves; and
removing a part of the semiconductor substrate between a bottom of the array of first grooves and the array of second grooves, such that the first groove and the array of second grooves are connected and merged to form a vertical array of semiconductor plates.

18. The method of claim 15, further comprising:
removing the first protection layer and second protection layer; and
separating a semiconductor plate devices from the substrate.

19. The method of claim 15, further comprising:
depositing a contact layer on part of the first-type doping region;
depositing another contact layer on part of the second-type doping region; and
separating semiconductor plate devices from the substrate.

20. The method of claim 15, further comprising:
depositing at least one layer of semiconductor on the main surfaces of the semiconductor plate.
